(19) United States
(12) Patent Application Publication
(10) Pub. No.: US 2013/0038324 A1
(43) Pub. Date: Feb. 14, 2013

(54) APPARATUS METHOD AND SYSTEM OF AN ULTRA SENSITIVITY OPTICAL FIBER MAGNETO OPTIC FIELD SENSOR

(71) Applicants: Dong Ho Wu, Olney, MD (US); Anthony Garzarella, Ellicott City, MD (US)

(72) Inventors: Dong Ho Wu, Olney, MD (US); Anthony Garzarella, Ellicott City, MD (US)

(21) Appl. No.: 13/572,642

(22) Filed: Aug. 11, 2012

Related U.S. Application Data
(60) Provisional application No. 61/522,908, filed on Aug. 12, 2011.

(51) Int. Cl. G01R 33/032

(52) U.S. Cl. 324/244.1

(57) ABSTRACT

An apparatus and system, capable of measuring the magnitude and direction of magnetic fields including an ultra-sensitive, wideband magneto optic (MO) sensor having magneto-optic crystals is disclosed herein. The sensor exploits the Faraday Effect and is based on a polarimetric technique. An ultra sensitivity optical-fiber magneto-optic field sensor measures a magnetic field with minimal perturbation to the field, and the sensor can be used for High-power microwave (HPM) test and evaluation; Diagnosis of radar and RF/microwave devices; Detection/measurement of weak magnetic fields (e.g., magnetic resonance imaging); Characterization of very intense magnetic fields (>100 Tesla, for example rail gun characterization); Detection of very low-frequency magnetic fields; Characterization of a magnetic field over an ultra broad frequency band (DC—2 GHz); Submarine detection; and Submarine underwater communication.

### RELATED APPLICATIONS

Pursuant to 35 USC §120, the present application is related to and a continuation of and claims the benefit of priority to U.S. Non-Provisional patent application Ser. No. 12/829,298, now published application US Publication No. 2010-0264904 Apparatus and System for a Quasi Longitudinal Mode Electro Optic Sensor for High Power Microwave Testing, filed on Jul. 1, 2010, which is herein incorporated by reference in its entirety, which is a continuation of related U.S. Non-Provisional patent application Ser. No. 12/205,766, now U.S. Pat. No. 7,920,263, Apparatus and System for Electro Magnetic Field Measurements and Automatic Analyses of Phase Modulated Optical Signals from Ellectrooptic Devices. Also, pursuant to 35 USC §119(e), the present application is related to and claims priority to U. S. Provisional Application for Patent 61/522,908, Apparatus Method and System of an Ultra Sensitivity Optical Fiber Magneto Optic Field Sensor, filed on Aug. 12, 2011, which is herein incorporated by reference in its entirety.

### FIELD OF THE INVENTION

The present invention is generally related to test and evaluation of the magnitude and direction of magnetic fields. In particular the present invention is directed to a sensor which can be used to obtain rail gun operational characterization and can be used to detect submarine as well as radio frequency and high power microwave emissions; further, the invention can also facilitate submarine communications.

### BACKGROUND OF THE INVENTION

B-dot sensors are presently widely used for high-power microwave test and evaluation. They are in general composed of a metallic loop antenna or coil that interacts with the magnetic field; the metal in the antenna or coil results in unacceptably large field perturbations. As a consequence, the magnetic field measured by the B-dot sensor is not true field, and it is often difficult or impossible to obtain reliable HPM T&E results with these B-dot sensors, particularly in confined spaces. In addition, B-dot sensors have a narrow bandwidth. To perform HPM T&E over a broad frequency bandwidth, several different B-dot sensors with complementary bandwidths are required. Third, the sensor size depends on the wavelength of the magnetic field that it measures. For low-frequency field characterizations the sensor size then becomes very bulky, and it is unable to measure smaller variations in the field patterns or other patterns near a complex collection of electronic devices.

The Hall probe is a convenient magnetic field sensor, used at room temperature. However, its sensitivity is several orders of magnitude poorer than that of Superconducting quantum-interference devices or the atomic vapor cell. In addition, it has a narrow dynamic range and a very limited frequency bandwidth (DC—kHz).

Superconducting quantum-interference devices (SQUIDs) are the most sensitive magnetometers that are commercially available. The operating bandwidth of SQUIDs is typically from DC to a few GHz. However, SQUIDs must be operated at cryogenic cooling temperatures, which are typically at or below −269° C. Cooling also requires that a SQUID be kept inside a cryogenic Dewar; thus the size of an operational SQUID is very bulky. The SQUID also contains metallic and superconducting components, which can interfere with the measurement of the electromagnetic field.

Atomic vapor cells are very sensitive magnetic field sensors, currently being developed by several research groups. A few of these groups have already demonstrated atomic vapor cells that have sensitivities exceeding those of SQUIDs. An atomic vapor cell requires an oven, which must keep the cell at a constant temperature, in order to produce atomic vapor. Although a state-of-the art atomic vapor cell uses a small oven, contained within the vapor cell device, vapor cells can only be used in limited applications, namely, those that do not alter the oven temperature.

The atomic vapor cell, spin exchange relaxation free atomic magnetometer and Squid technologies with sensitivity in the range from 300 fT/Hz^{1/2} to 0.54 fT/Hz^{1/2}, where 1 ft (femto Tesla)=10⁻¹⁵ Tesla. However, the SQUID requires liquid helium for cooling.

Therefore, the need exists for devices and systems capable of measuring the magnitude and direction of magnetic fields, while reducing large field perturbations, resulting from metal in the metallic loop antenna or coil.

Also, the need exists for devices and systems capable of measuring the magnitude and direction of magnetic fields, having high sensitivity, along with a wideband frequency and wide dynamic range.

Finally, the need exists for devices and systems capable of measuring the magnitude and direction of magnetic fields, which do not require either cryogenic cooling or an oven to obtain a constant temperature.

### SUMMARY OF THE INVENTION

An apparatus and system, capable of measuring the magnitude and direction of magnetic fields employing an ultra-sensitive, wideband magneto-optic sensor having magneto-optic crystals is disclosed herein. The sensor exploits the Faraday Effect and is based on a polarimetric technique.

An ultra sensitivity optical-fiber magneto-optic (MO) field sensor has been invented, which is able to measure a magnetic field with minimal perturbation to the field, and it can be used for various purposes. Some examples of its applications are: Rail gun characterizations, High-power microwave (HPM) test and evaluation; Diagnosis of radar and RF/microwave devices; Detection/measurement of weak magnetic fields (e.g., magnetic resonance imaging); Characterization of very intense magnetic fields (>100 Tesla); Detection of very low-frequency magnetic fields; Characterization of a magnetic field over an ultra broad frequency band (DC—2 GHz); Submarine detection; and Submarine underwater communication.

When a light beam propagates through a magneto-optic medium of length L, the application of an external magnetic field B along the path of the light beam causes a rotation φ of the plane of polarization of the beam. This is called the Faraday Effect. The rotation φ can be expressed as φ=VBL where V is the Verdet constant of the MO medium (hereafter V 120), and L is the length of the MO crystal medium, (hereafter L 108), and B is the strength of an external magnetic field (hereafter Bₑₓₜₑᵣₙₐₗ 140 or Bₑₓₜ 140). By measuring the rotation φ (hereafter angle phi (φ 130)) the strength of the magnetic field B can be extracted (i.e., mathematically determined). Of currently available MO materials, bismuth-doped rare-earth iron garnet (BiGdLu)₃(FeGa)₅O₁₂ thick film (denoted as Bi:RIG in short) exhibits the largest value for the Verdet constant. The instant invention is an MO sensor based on Bi:RIG thick films and demonstrates a very high sensitivity, of about 1 Pico-Tesla/(Hz)^{1/2} or better. The sensor can be used over the frequency range from DC to 2 GHz.

### BRIEF DESCRIPTION OF THE DRAWINGS

FIG. 1 illustrates the Faraday Effect, where: Eₒₚₜ is the optical field of the light beam, and Bₑₓₜ is an external magnetic field applied to the MO crystal.

FIG. 2 illustrates Verdet constants for different materials for the probe (laser) beam wavelength between 633-670 nm (taken from different sources).

FIG. 3 illustrates a schematic diagram of a stacked magneto-optic field sensor in the transmissive-mode configuration, where each of five MO crystals stacked together has antireflection coatings on two sides of each of the stacked MO crystals. In this illustration each MO crystal is a bismuth-doped rare-earth iron garnet (BiGdLu)₃(FeGa)₅O₁₂ thick film (denoted as Bi:RIG in short).

FIG. 4A illustrates the cross polarization configuration of the two polarizers: the polarization directions P₁ and P₂ (i.e., First Polarizer and Second Polarizer, respectively) are perpendicular to each other.

FIG. 4B illustrates off-cross-polarization: where the polarization angle between P₁ and P₂ is 80°.

FIG. 5A illustrates a modulated amplitude A as a function of φ (the polarization modulation).

FIG. 5B illustrates the modulated amplitude A as a function of probe-beam (laser) power (P).

FIG. 6 illustrates a schematic diagram of an amplifier module for a simultaneous measurement of AC and DC signals. By measuring the AC and DC signals simultaneously, one can reduce the measurement error of the MO signal.

FIG. 7A(1), FIG. 7A(2), FIG. 7A(3) and FIG. 7A(4) illustrate four MO sensors with stacked Bi:RIG thick film structures in the sensor head. FIG. 7A(1) illustrates a configuration of two MO Crystals stacked together in the sensor head; FIG. 7A(2) illustrates a configuration of four

MO Crystals stacked together in the sensor head; FIG. 7A(3) illustrates a configuration of seven or eight MO crystals stacked together in the sensor head; and FIG. 7A(4) illustrates a configuration of ten plus MO crystals stacked together in the sensor head.

FIG. 7B(1), FIG. 7B(2), FIG. 7B(3) and FIG. 7B(4) illustrate the modulation pulse height for various stacks of Bi:RIG MO crystals stacked in a given sensor head from N=1, N=2, N=3, and N=4 respectively.

FIG. 8 illustrates sensitivity as a function of stacking number N number of Bi:RIG thick films. Experimental results were obtained with anti-reflection coated (thick-film) crystals under a fixed, 100 A/m pulsed field (4 ns).

FIG. 9 illustrates linearity of MO modulation signal as a function of magnetic field strength at 100 MHz (CW), using a MOS-23 (a MO sensor with 23 stacked MO thick films) device.

FIG. 10 illustrates the frequency response of the MO sensor. A similar frequency response was obtained regardless of the number of stacked Bi:RIG thick films installed on the MO sensor head.

FIG. 11A illustrates a schematic of a transmissive mode MO sensor configuration.

FIG. 11B illustrates a schematic of a reflective mode MO sensor configuration.

FIG. 11C illustrates a schematic of a multi path mode MO sensor configuration.

FIG. 12A, FIG. 12B and FIG. 12C illustrate a schematic of a comparison of dynamic ranges for different magnetometers, as shown in Table I.; a schematic of a comparison or ranges of magnetometer operating frequencies, as shown in Table II; and a schematic of a comparison of other specifications of magnetometers, as shown in Table III, respectively.

### DETAILED DESCRIPTION OF THE INVENTION

Preferred exemplary embodiments of the present invention are now described with reference to the figures, in which like reference numerals are generally used to indicate identical or functionally similar elements. While specific details of the preferred exemplary embodiments are discussed, it should be understood that this is done for illustrative purposes only. A person skilled in the relevant art will recognize that other configurations and arrangements can be used without departing from the spirit and scope of the preferred exemplary embodiments. It will also be apparent to a person skilled in the relevant art that this invention can also be employed in other applications. Further, the terms “a”, “an”, “first”, “second” and “third” etc. used herein do not denote limitations of quantity, but rather denote the presence of one or more of the referenced items(s).

According to exemplary embodiments, an apparatus and system, capable of measuring the magnitude and direction of magnetic fields employing an ultra-sensitive, wideband MO sensor having magneto-optic crystals 150, by exploiting the Faraday Effect is based on the polarimetric technique, as disclosed herein.

An ultra sensitivity optical-fiber magneto-optic (MO) field sensor has been invented, which is able to measure a magnetic field Bₑₓₜₑᵣₙₐₗ 140 with minimal perturbation to the magnetic field Bₑₓₜₑᵣₙₐₗ 140, further, the MO sensor can be used for various purposes. Some examples of its applications are: Rail gun characterization, High-power microwave (HPM) test and evaluation; Diagnosis of radar and RF/microwave devices; Detection/measurement of weak magnetic fields (e.g., magnetic resonance imaging); Characterization of very intense magnetic fields (>100 Tesla); Detection of very low-frequency magnetic fields; Characterization of a magnetic field over an ultra broad frequency band (DC—2 GHz); Submarine detection; and Submarine underwater communication.

When a light beam such as laser probe beam 1132 propagates through a magneto-optic medium of length L 108, the application of an external magnetic field B (such as Bₑₓₜₑᵣₙₐₗ 140) along the path of the light beam 1132 causes a rotation the angle phi φ 130 of the plane of polarization of the beam 1132. This is called the Faraday Effect, which can be expressed as

φ=VBL (1)

where V is the Verdet constant. The Verdet constant is dependent on the material, and it varies with the wavelength λ of the light beam 1132.

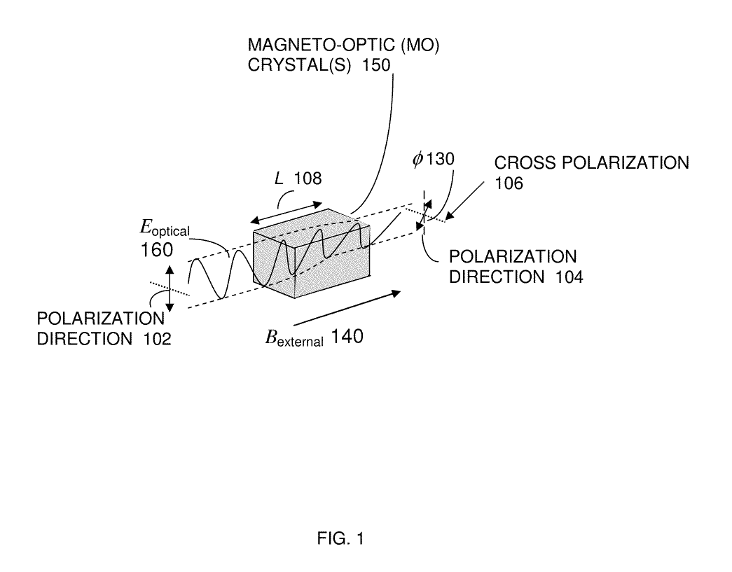

Regarding the Faraday Effect and referring to FIG. 1, Eₒₚₜ is the optical field of the light beam, and Bₑₓₜ 140 is an external magnetic field applied to the MO crystal 150.

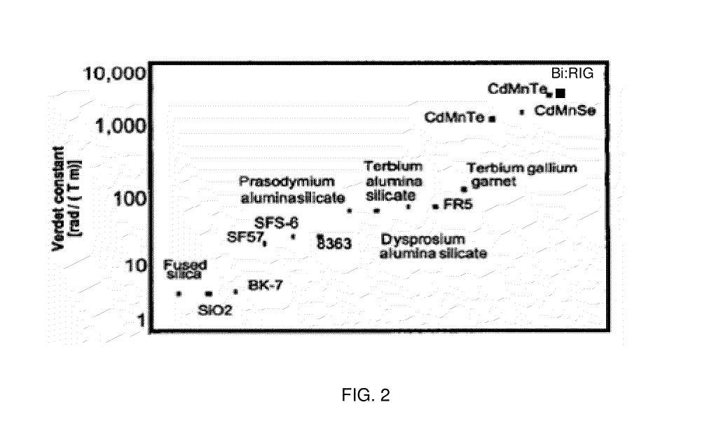

There are a number of MO materials currently available. FIG. 2 shows the Verdet constants for some of these materials. By experimentation, it has been determined that a MO sensor based on bismuth-doped rare-earth iron garnet (BiGdLu)₃(FeGa)₅O₁₂ films (denoted as Bi:RIG in short) had the highest sensitivity, and they responded only to the magnetic field. While other MO materials, such as CdMnTe, have a high MO responsivity, they exhibit a parasitic electro-optic effect. In other words, they responded to the magnetic field, as well as to the electric field, making the material unsuitable for magnetic field sensing.

According to exemplary embodiments, the MO sensor is based on the polarimetric technique. While it shares a similar structural design with a related electro-optic (EO) field sensor, for which a referenced disclosure was submitted in 2008, there are several different design parameters for this MO sensor and herein incorporated by reference in its entirety.

Bismuth-doped rare-earth iron garnet (Bi:RIG) crystal (the best among presently available MO materials) has a film thickness of 0.5 mm. As indicated in Equation (1), the sensitivity of the MO sensor depends on the length of the crystal. In order to increase the effective length of the MO material, we have had to stack the Bi:RIG films together. Stacking the films, however, generates reflections between the crystals, which not only reduce the intensity of the transmitted probe beam but also could lead to undesirable Fabry-Perot interferometric interference. By depositing antireflection coatings 302 on the MO films, these reflection effects can be prevented.

According to exemplary embodiments, the MO sensor disclosed herein contains multiple optical components and MO crystals 150. The sensor housing 314 must be rigid, in order to ensure that these components are well aligned and prevented from any movement, and the (probe) laser beam 1132 traverses these components without distortion. A ceramic housing is used to achieve these configurations. This is important, because measurements of rotations of the polarization angle phi φ 130 as small as one arc-second, must be obtained in order to detect very weak magnetic fields.

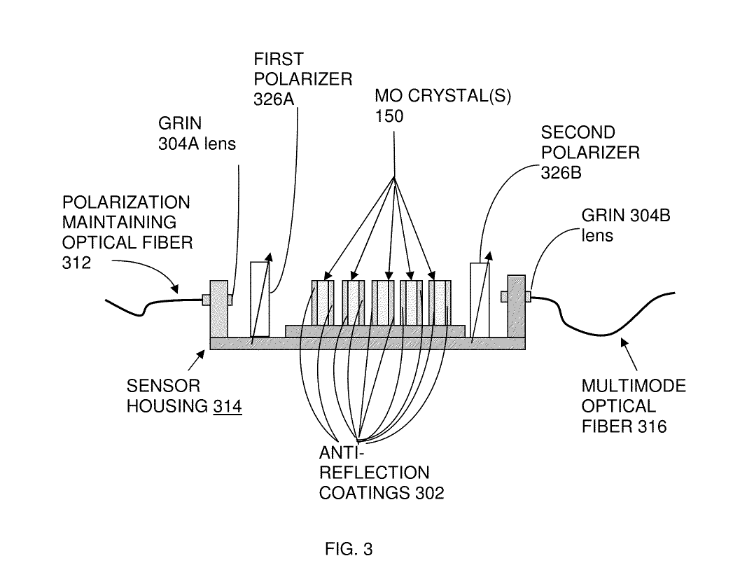

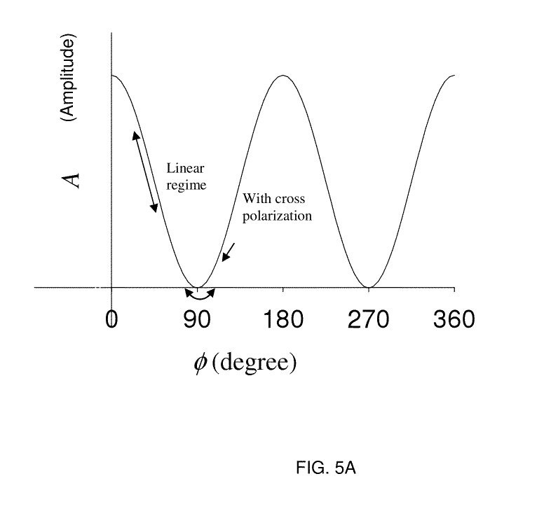

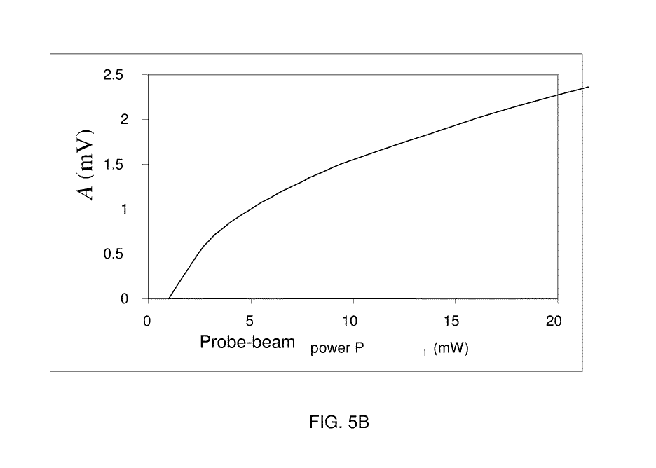

Referring to FIG. 3, the magneto optic field sensor in the transmissive mode is illustrated. According to exemplary embodiments and referring to FIG. 3, FIG. 5A and FIG. 5B, in this sensor design, a polarimetric technique is used, in which the rotation of the polarization of the light beam φ 130 (the polarization modulation) is converted into an amplitude modulation as the light beam passes through the second polarizer (polarizer 2). The modulated amplitude A can be expressed in terms of the optical field of the light beam Eₒₚₜ 160 and the polarization direction of polarizer 2, P₂, (see formula (2)):

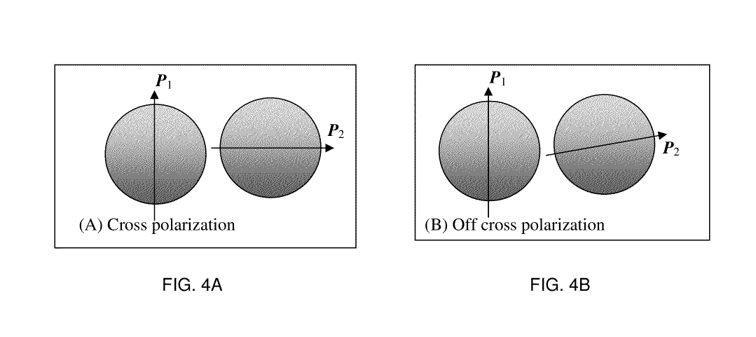

A=(Eₒₚₜ·P₂)²=|Eₒₚₜ|²|P₂|² cos²(φ₀+φ) (2)

where φ₀ is the angle of polarization of polarizer 2 with respect to the vertical, that is, the initial polarization direction of Eₒₚₜ 160. The amplitude A of the modulated light beam is measured by the photo-detector, and the magnetic field strength |Bₑₓₜ| is determined from the measured A. FIG. 5A shows the modulated amplitude A as a function of the rotation of polarization φ (i.e., the polarization modulation). Typically the polarization direction of polarizer 2 (see FIG. 3 and FIG. 4A) is set to be perpendicular to the initial polarization direction of the light beam 1132 (the polarization direction of polarizer 1). This is called the cross polarization (see FIG. 1, FIG. 4A and FIG. 4B) configuration, which enables the detection of a minute change in the polarization direction of the light beam 1132, while keeping the optical noise at a minimum.

Referring to FIG. 3, FIG. 4A and FIG. 5A, with such a configuration, according to exemplary embodiments, the amplitude variation typically occurs near a trough (or a crest), and the output is nonlinear, as shown in FIG. 5A. Note, FIG. 5B illustrates the modulated amplitude A as a function of probe-beam 1132 (laser) power (P.) If P₂ is set to be slightly (˜10°) off from the cross polarization configuration (see FIG. 4 B), the amplitude variation occurs in the linear regime. Since the slope of the linear regime is steeper than the slop near a trough, the output is larger for the same amount of variation of φ 130. However, operation in the linear regime tends to be susceptible to external optical noise. According to exemplary embodiments, the MO sensors disclosed herein are configured either the cross-polarization 106 (see FIG. 4A) configuration or the off-cross-polarization (i.e. linear regime) configuration (see FIG. 4B), depending on the measurement environment and the type of applications. In the cross polarization 106 configuration of the two polarizers, the polarization directions P₁ and P₂ are perpendicular each other (see FIG. 4A). In the off-cross-polarization configuration, the polarization angle between P₁ and P₂ is 80° (see FIG. 4B). For most applications, the off-cross-polarization configuration is used.

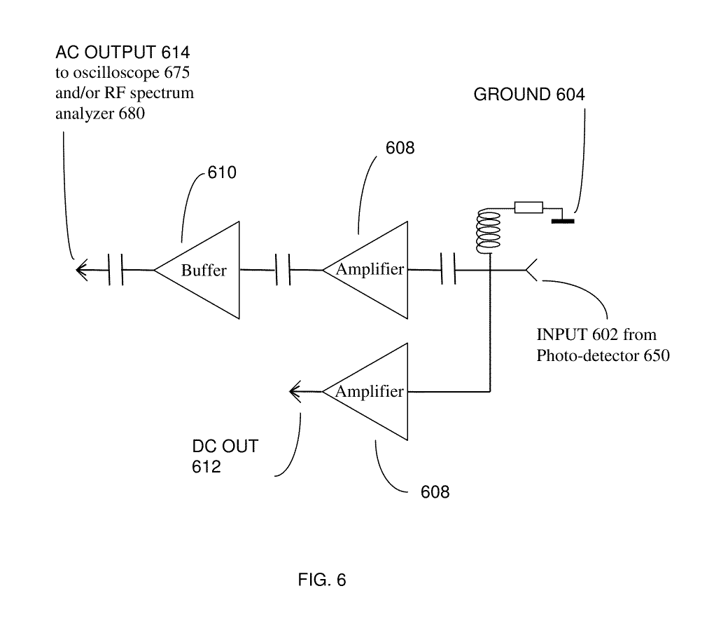

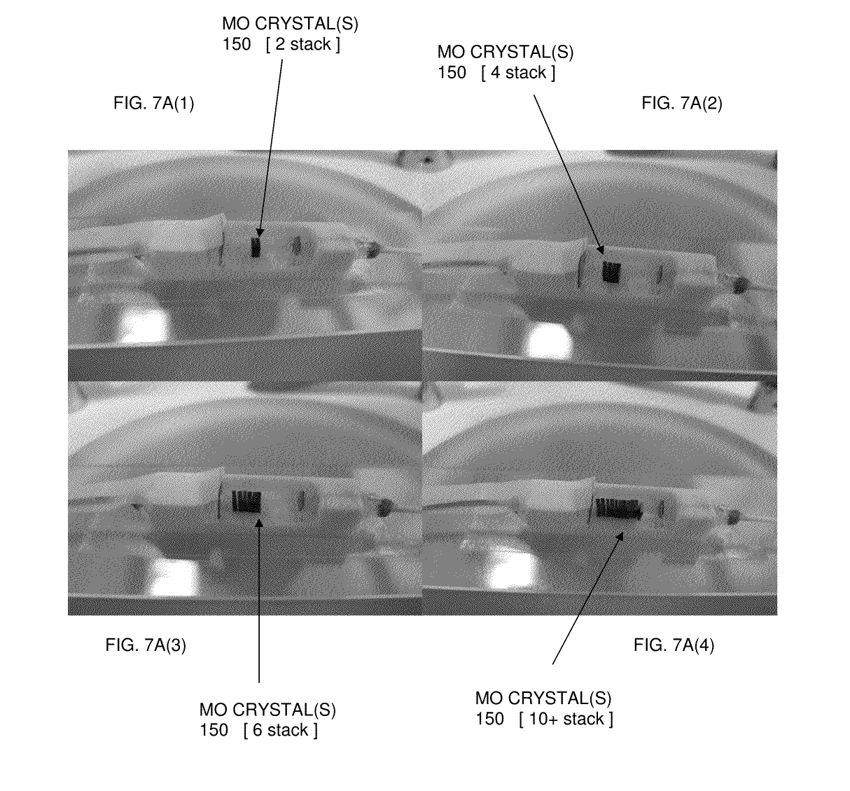

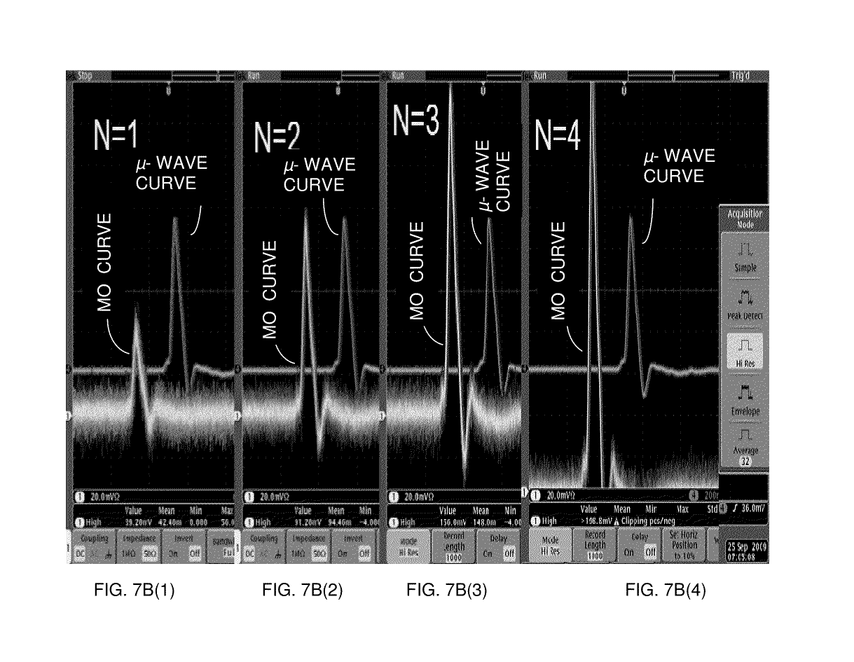

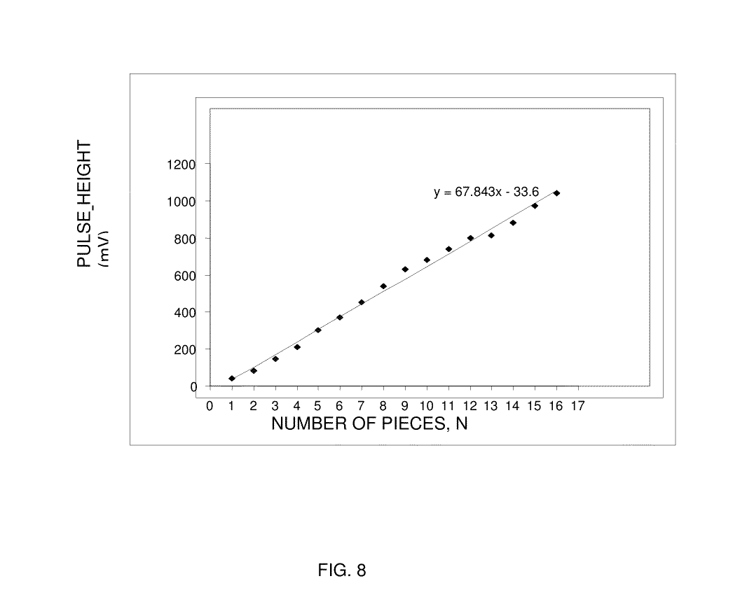

According to exemplary embodiments and referring to FIG. 4A, FIG. 4B, FIG. 5A and FIG. 6, the modulated amplitude A changes as a function of the polarization rotation φ 130. The modulated amplitude A also depends on the power of the laser probe beam 1132, as shown in FIG. 5B.

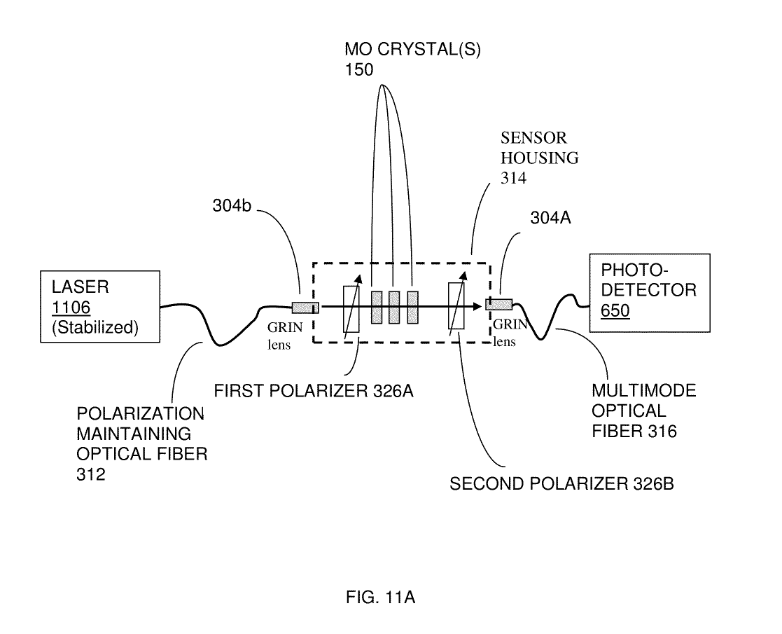

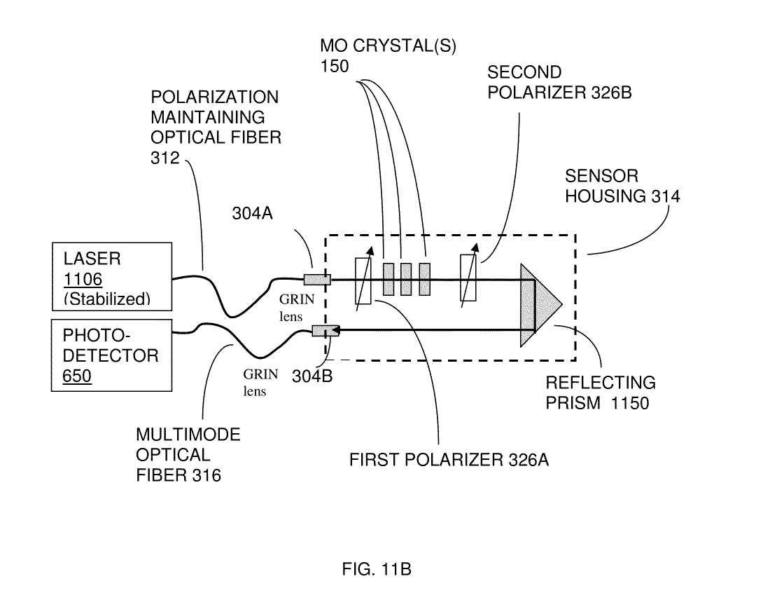

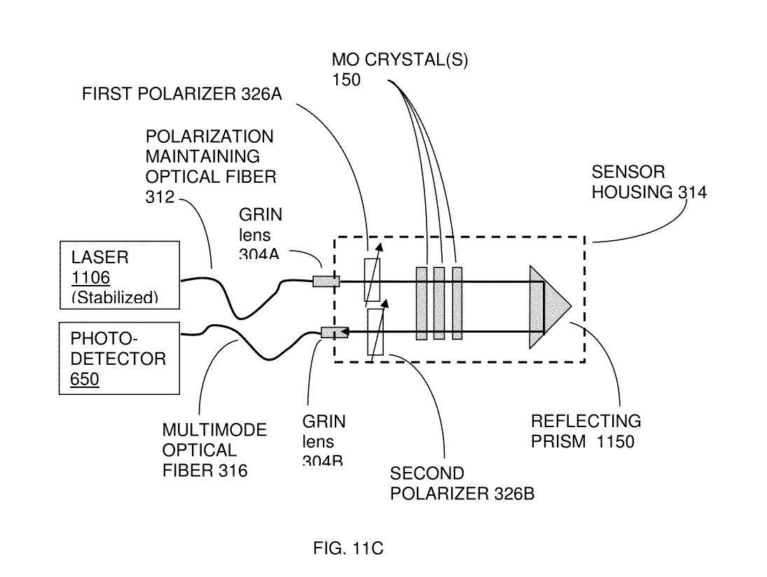

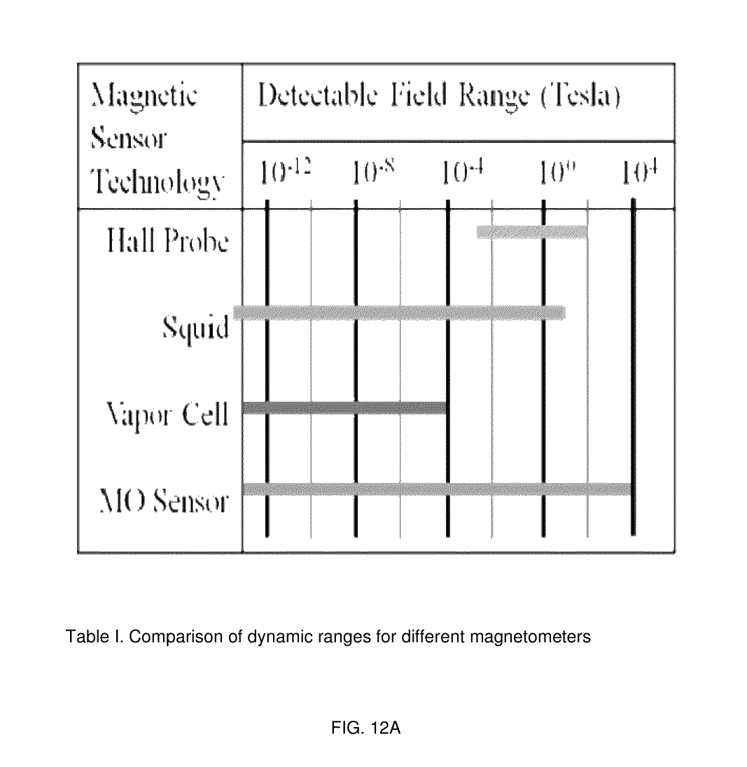

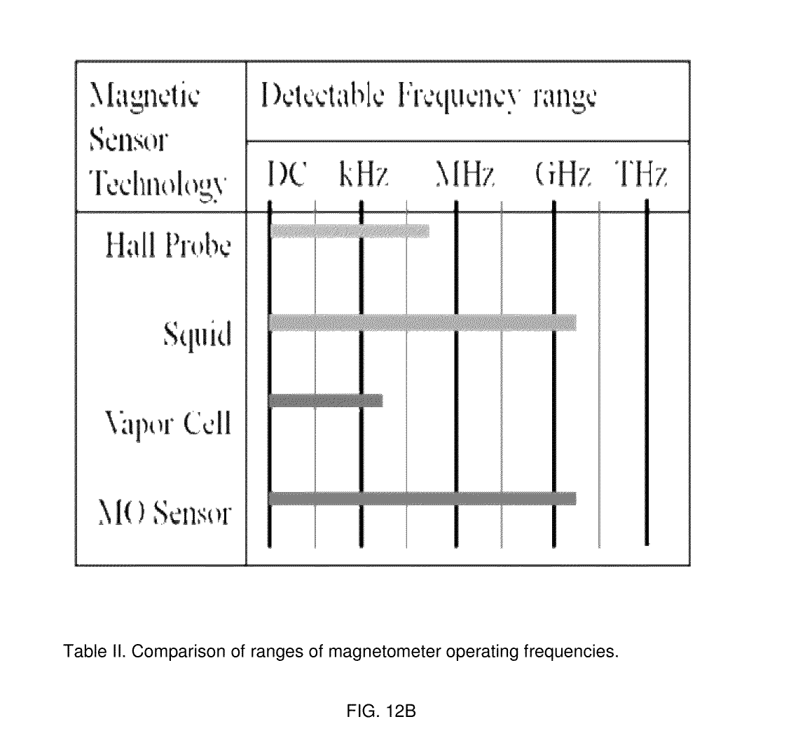

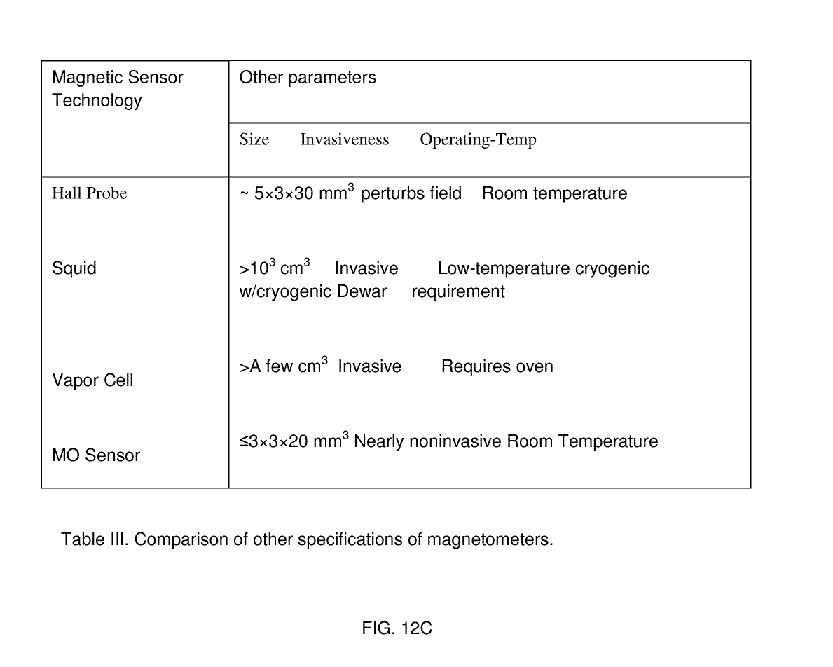

Hence fluctuations in the laser probe beam 1132 power results in the measurement error of the MO signal, which in turn results in the measurement error of the magnetic field Bₑₓₜₑᵣₙₐₗ 140. One can reduce such measurement error of the MO signal by measuring the AC and DC signals simultaneously from an amplifier of which schematic diagram is shown in FIG. 6. In order to achieve a high sensitivity, the MO sensor measures the rotation of polarization φ 130 as small as one arc-second, which is equivalent to a very small change in A. Ideally, if the laser probe beam and optical components are perfectly stable and do not produce any noise, such a change only takes place because of the Faraday Effect and a change in the magnetic field Bₑₓₜₑᵣₙₐₗ 140. However, in reality, the laser 1106 (see FIG. 11D) is prone to instability and the optical components tend to produce some optical noise, which lead to changes in the polarization and the amplitude of a probe beam, both of which compromise the sensitivity of MO sensor. By employing a stable probe beam 1132 and stable optical components, these problems can be minimized. There is also an additional technique for resolving problems associated with laser instability and optical noise. According to exemplary embodiments, to amplify the MO signal from the photo-detector an amplifier as shown schematically in FIG. 6 is employed. For time-varying magnetic fields, such as Bₑₓₜₑᵣₙₐₗ 140, both the AC output and the DC output from the amplifier are measured. Typically, fluctuations in the amplitude of the laser beam 1132 or polarization are much slower than the time-varying magnetic-field signal, which is faster than 1 MHz for most applications. Hence the MO signal variations from such fluctuations can be corrected by measuring the ratio of the AC and DC outputs. By employing this method, measurements of polarization rotations of a few arc-seconds in our experiments are achieved. According to exemplary embodiments, a probe laser (such as laser 1106) that had a stability of 1 MHz at a wavelength of 1550 nm is used.

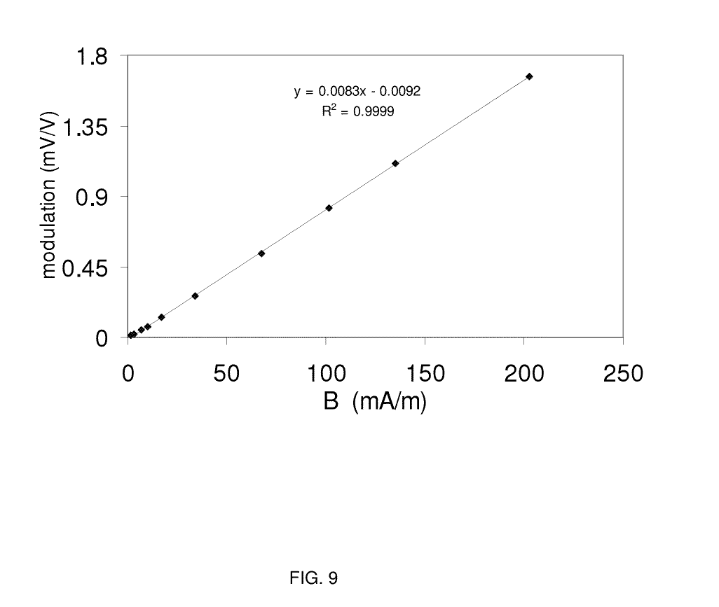

According to exemplary embodiments, the dynamic range of the MO sensor is larger than 9 orders of magnitude as compared to other types of existing magnetometers. As expected from Equation (1) the MO output is linear with the external magnetic field strength (see FIG. 9), which illustrates the linearity of the MO modulation signal as a function of magnetic field strength at 1000 MHz, continuous wave (CW), using MOS-23 device (a MO sensor with 23 stacked MO thick films).

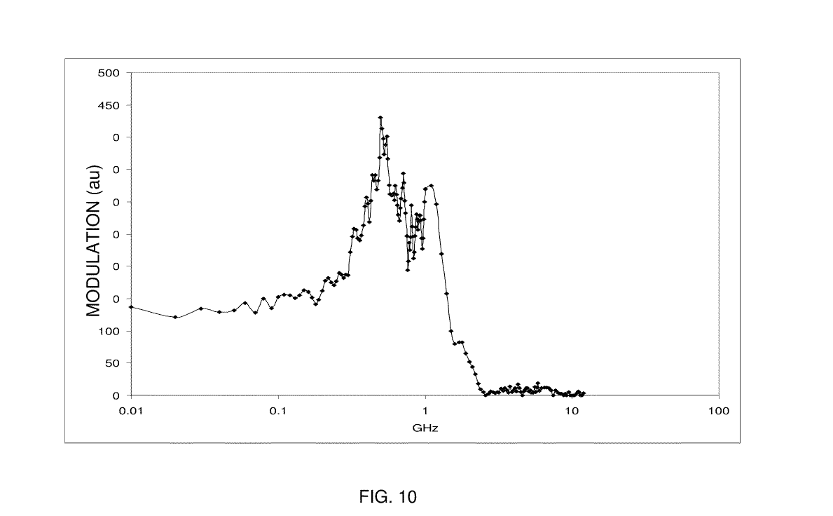

According to exemplary embodiments, the frequency response of the MO sensor was measured using a microstrip (below 1 GHz) and a double-ridged horn antenna (from 1 to 12 GHz). Referring to FIG. 10, the result is for a MO sensor with thick-film stack of ten (MOS-10). The responsivity reaches its peak value at about 500 MHz, and quickly falls off after 1 GHz. When experiments were performed with several stacked Bi:RIG thick films or with a single piece of Bi:RIG thick film, they exhibited a similar frequency response. The bandwidth, limited to 2 GHz, seems to be associated with the thick film's crystal properties. To increase the sensitivity of the MO sensor, while increasing the bandwidth, a delicate balance between the optimum amount of bismuth dopant and the crystal anisotropy of Bi:RIG thick film must be achieved. According to exemplary embodiments, the material is modified by dilution on the iron site to minimize the cubic magneto-crystalline anisotropy K₁. This improves the frequency bandwidth of the material.

Referring to FIG. 11A, FIG. 11B, and FIG. 11C (also, see FIG. 11D) and according to exemplary embodiments, the MO sensor is fabricated in at least three different geometrical configurations: (1) transmissive mode (FIG. 11A and FIG. 11D), (2) reflective mode (FIG. 11B) and (3) multi-path mode (FIG. 11C), respectively.

Advantages and Novel Features:

According to exemplary embodiments, the MO sensor is made entirely of dielectric material so that it can measure a magnetic field Bₑₓₜₑᵣₙₐₗ 140 with minimal perturbation.

Bismuth-doped rare earth iron garnet (BiGdLu)₃(FeGa)₅O₁₂ thick films were used for the MO sensor. The Verdet constant of the material is measured to be 2×10⁴ rad/T-m, which is the highest among the currently available (or synthesized) MO materials (see FIG. 2).

The sensitivity can be increased by stacking (BiGdLu)₃(FeGa)₅O₁₂ thick films. With 14 (BiGdLu)₃(FeGa)₅O₁₂ thick films stacked in series, the MO sensor demonstrated a minimum detectable field of 0.2 mA/m for a CW (continuous wave) signal at 1 GHz. An RF spectrum analyzer with a 5 kHz bandwidth was used as the readout instrument, and signal averaging was employed to reduce the noise. This indicates that the MO sensor with 14 stacked Bi:RIG thick films has a sensitivity of 2.8 μA/m-√GHz, which is equivalent to 3 pT/√Hz. This compares favorably with the sensitivity of low-end SQUIDs (Superconducting Quantum interference Devices), which require cryogenic cooling. Considering that the MO sensor does not require cooling, it has a significant advantage over SQUIDs. By stacking more Bi:RIG thick films, the MO sensor achieves higher sensitivity. Thus, according to exemplary embodiments, the ultra wideband, high sensitivity magnetic field MO sensor achieves a maximum sensitivity of 10⁻¹² to 10⁻¹³ T/Hz^{1/2} over the frequency range from DC to 2 GHz; therefore, while the MO sensor has a sensitivity comparable to state-of-the art magnetometers, the structure of the MO sensor is less complicated than those state-of-the art magnetometers (SQUIDs and atomic vapor cells).

As can be seen in Tables I and II, the MO sensor according to exemplary embodiments has a much wider dynamic range and wider frequency ranges, as compared to conventional magnetometers. Further, while the MO sensor with 14 stacked Bi:RIG thick films can detect a magnetic field as weak as 0.2 mA/m, a MO sensor can be reconfigured to measure a very intense magnetic field exceeding 8×10⁸ A/m. And, the MO sensor has several other advantages, including smaller size, noninvasiveness, as well as, room temperature operation, as shown in Table III.

While (BiGdLu)₃(FeGa)₅O₁₂ thick film is used in exemplary embodiments for the MO sensor (it has the largest Verdet constant and responds only to a magnetic field Bₑₓₜₑᵣₙₐₗ 140, not to an electric field), however, the MO sensor design can be used with other MO materials.

In exemplary embodiments, a polarization maintaining (PM) optical fiber 312 is used for the probe beam 1132 input, and a multi-mode (MM) optical fiber 316 is used for the MO output. However, in additional exemplary embodiments, the MO sensor is fabricated with any combination of optical fibers; for example, either two PM 312 fibers or two MM 316 fibers, or one MM fiber 316 for the probe beam 1132 input and one PM 312 fiber for the MO output.

The preferred embodiments include:

A system measuring a magnitude and a direction of a magnetic field Bₑₓₜₑᵣₙₐₗ 140, employing an ultra-sensitive, wideband magneto-optic sensor having a set of one or more magneto-optic crystals 150. The system comprises an analyzing stage 1136, including a laser 1106, a photodetector 650, and a set of one or more measurement instruments, such as an RF spectrum analyzer 680, an oscilloscope 675 and DC measurements. The laser 1106 transmits an optical field of a light beam 1132 which passes through the set of one or more magneto-optic crystals 150. The set of one or more magneto-optic crystals 150 is exposed to an external magnetic field Bₑₓₜₑᵣₙₐₗ 140.

The system contains a sensor housing 314, which includes the ultra-sensitive, wideband magneto-optic sensor, where the ultra-sensitive, wideband magneto-optic sensor further includes a first gradient index (GRIN) lens 304A, a second gradient index (GRIN) lens 304B, a first polarizer 326A, a second polarizer 326B and the set of one or more magneto-optic crystals 150. Polarization maintaining optical fiber 312 is cooperative connected between the analyzing stage 1136 and first gradient index (GRIN) lens 304A. A multimode optical fiber 316 is connected between the second gradient index (GRIN) lens 304B and the analyzing stage 1136. The polarization maintaining optical fiber 312 permits the optical field of the light beam 1132 to enter and pass through the first polarizer 326A then through the magneto-optic crystal 150, wherein said optical field of said light beam 1132 has an interaction with a magnetic field Bₑₓₜₑᵣₙₐₗ 140 pulse under test in proximity to the magneto-optic crystal 150. The magnetic field Bₑₓₜₑᵣₙₐₗ 140 pulse under test, is irradiated onto the magneto-optic crystal 150 the magneto-optic crystal 150 generates a magneto-optic pulse caused by the interaction with the magnetic field Bₑₓₜₑᵣₙₐₗ 140 pulse. The magneto-optic pulse exits the magneto-optic crystal 150 and passes through the second polarizer 326B and through the second gradient index lens 304B, which is cooperatively connected to a multimode optical fiber 316, which is an exit pathway from the sensor housing for said magneto-optic pulse and the magnetic field Bₑₓₜₑᵣₙₐₗ 140 pulse.

The apparatus for measuring a magnitude and a direction of a magnetic field Bₑₓₜₑᵣₙₐₗ 140 includes the magneto-optic crystal 150 having a length L 108, wherein the magneto-optic crystal includes at least a set of two anti-reflection coatings 302 on two ends of the magneto-optic crystal. The apparatus, further includes a set of at least two or more magneto-optic crystals 150 stacked together, having at least the length 2 L or more and the set of two anti-reflection coatings 302 on two ends of the magneto-optic crystal 150 include an air gap between anti-reflection coatings 302 and the magneto-optic crystal 150 to prevent Fabry-Perot interferometric interference.

While the exemplary embodiments have been particularly shown and described with reference to preferred embodiments thereof, it will be understood, by those skilled in the art, that the preferred embodiments including the first exemplary embodiment, and the second exemplary embodiment, etc. have been presented by way of example only, and not limitation; furthermore, various changes in form and details can be made therein without departing from the spirit and scope of the invention. Thus, the breadth and scope of the present exemplary embodiments should not be limited by any of the above described preferred exemplary embodiments, but should be defined only in accordance with the following claims and their equivalents. All references cited herein are each entirely incorporated by reference herein, including all data, tables, figures, and text presented in the cited references. Also, it is to be understood that the phraseology or terminology herein is for the purpose of description and not of limitation, such that the terminology or phraseology of the present specification is to be interpreted by the skilled artisan in light of the teachings and guidance presented herein, in combination with the knowledge of one of ordinary skill in the art.

The foregoing description of the specific embodiments will so fully reveal the general nature of the invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein.

What is claimed is:

1. A system measuring a magnitude and a direction of a magnetic field, including an ultra-sensitive, wideband magneto-optic sensor having a set of one or more magneto-optic crystals, having minimal perturbation of the magnetic field measured by the system, the system comprising:
an analyzing stage, including a laser, a photodetector and a set of one or more measurement instruments, wherein the laser transmits an optical field of a light beam which passes through the set of one or more magneto-optic crystals, and wherein the set of one or more magneto-optic crystals is exposed to an external magnetic field;
a sensor housing containing the ultra-sensitive, wideband magneto-optic sensor, wherein the ultra-sensitive, wideband magneto-optic sensor includes a first gradient index (GRIN) lens, a second gradient index (GRIN) lens, a first polarizer, a second polarizer and the set of one or more magneto-optic crystals, wherein a polarization maintaining optical fiber is interposed as a first cooperative connection between the analyzing stage and first gradient index (GRIN) lens, and wherein a multimode optical fiber is interposed as a second cooperative connection between the second gradient index (GRIN) lens and the analyzing stage, wherein the polarization maintaining optical fiber cooperatively permits the optical field of the light beam to enter and pass through the first polarizer then through the magneto-optic crystal, wherein said optical field of said light beam has an interaction with a magnetic field pulse under test in proximity to the magneto-optic crystal and wherein said magnetic field pulse under test, having been irradiated onto the magneto-optic crystal said magneto-optic crystal generates a magneto-optic pulse caused by the interaction with the magnetic field pulse, and said magneto-optic pulse exits the magneto-optic crystal and passes through the second polarizer and through the second gradient index lens, which is cooperatively connected to a multimode optical fiber, which is an exit pathway from the sensor housing for said magneto-optic pulse and the magnetic field pulse.

2. The system according to claim 1, wherein the set of one or more measurement instruments includes an RF spectrum analyzer, an oscilloscope and a set of one or more direct current measurement instruments.

3. The system of claim 1, wherein a polarization alignment of the second polarizer and the analyzer stage is a non-orthogonal polarization alignment.

4. The system of claim 1, wherein the sensor housing is composed of rigid, shatter-resistant ceramic to ensure precision measurement of polarization rotation angle phi, wherein minimum perturbation of the magnetic field being measured is obtained.

5. The system of claim 1, further comprising having a set of at least two or more magneto-optic crystals stacked together, wherein each of the set of at least two or more magneto-optic crystals stacked together includes at least two anti-reflection coatings on two ends of the magneto-optic crystal, and wherein coating the set of at least two or more magneto-optic crystals increases sensitivity and stability of the magneto-optic sensor.

6. The system of claim 5, wherein the set of two anti-reflection coatings on two ends of the magneto-optic crystal includes an appropriate air gap between anti-reflection coatings and the magneto-optic crystal to prevent Fabry-Perot interferometric interference.

7. The system of claim 5, wherein the magneto-optic sensor is configured in a transmissive mode.

8. The system of claim 5, wherein the magneto-optic sensor is configured in a reflective mode.

9. The system of claim 5, wherein the magneto-optic sensor is configured in a multipath mode.

10. The system of claim 5, wherein AC and DC signals are measured simultaneously.

11. An apparatus measuring a magnitude and a direction of a magnetic field, having an ultra-sensitive, wideband magneto-optic sensor including a set of one or more magneto-optic crystals, having minimal perturbation of the magnetic field measured by the apparatus, the apparatus comprising:
a sensor housing containing a magneto-optic crystal having a length L, wherein the magneto-optic crystal includes at least a set of two anti-reflection coatings on two ends of the magneto-optic crystal;
a first polarizer and a second polarizer residing in the sensor housing, wherein the first polarizer and the second polarizer are configured in the sensor housing in close proximity to the magneto-optic crystal on one of each end of the magneto-optic crystal; and
a first gradient index lens and a second gradient index lens residing in the sensor housing, wherein the first gradient index lens and the second gradient index lens are cooperatively configured in the sensor housing in close proximity to the first polarizer and the second polarizer, wherein the first gradient index lens is cooperatively connected to a polarization maintaining optical fiber which permits an optical field of a light beam to enter and pass through the first polarizer then through the magneto-optic crystal, wherein said optical field of said light beam has an interaction with a magnetic field pulse under test in proximity to the magneto-optic crystal and wherein said magnetic field pulse under test, having been irradiated onto the magneto-optic crystal, said magneto-optic crystal generates a magneto-optic pulse caused by the interaction with the magnetic field pulse, and said magneto-optic pulse exits the magneto-optic crystal and passes through the second polarizer and through the second gradient index lens, which is cooperatively connected to a multimode optical fiber, which is an exit pathway from the sensor housing for said magneto-optic pulse and the magnetic field pulse.

12. The apparatus of claim 11, further having a set of at least two or more magneto-optic crystals stacked together, having at least the length 2 L or more, wherein each of the set of at least two or more magneto-optic crystals stacked together includes at least two anti-reflection coatings on two ends of the magneto-optic crystal, and wherein coating the set of at least two or more magneto-optic crystals increases sensitivity and stability of the magneto-optic sensor.

13. The apparatus of claim 11, wherein the set of two anti-reflection coatings on two ends of the magneto-optic crystal include an appropriate air gap between anti-reflection coatings and the magneto-optic crystal to prevent Fabry-Perot interferometric interference.

14. The apparatus of claim 11, wherein the sensor housing is composed of rigid shatter-resistant ceramic to ensure precision measurement of polarization rotation angle phi, wherein minimum perturbation of the magnetic field being measured is obtained.

15. The apparatus of claim 11, wherein a polarization alignment of the second polarizer and an analyzer stage is a non-orthogonal polarization alignment.
